(19) United States
(12) Patent Application Publication
(10) Pub. No.: US 2025/0132752 A1
(43) Pub. Date: Apr. 24, 2025

(54) ALTERNATING CURRENT SIGNAL TRANSFER APPARATUS AND ALTERNATING CURRENT APPARATUS

(71) Applicant: Laser Systems Inc., Tokushima (JP)

(72) Inventor: Yasuo OHNO, Tokushima (JP)

(21) Appl. No.: 18/918,173

(22) Filed: Oct. 17, 2024

(30) Foreign Application Priority Data
Oct. 20, 2023 (JP) 2023-181153

(51) Int. Cl. H03H 17/08; H02J 50/00; H02J 50/20; H02J 50/90

(52) U.S. Cl. CPC H03H 17/08; H02J 50/005; H02J 50/20; H02J 50/90

(57) ABSTRACT

An alternating current signal transfer apparatus includes: a transmission line; a plurality of first phase shifters connected to the transmission line at a branching point; a plurality of resonator pairs including a power transmitting coil and a power receiving coil and each connected to each of the plurality of first phase shifters; and a plurality of second phase shifters each connected to each of the plurality of resonator pairs. The plurality of second phase shifters are connected at a connecting point.

### CROSS REFERENCE TO RELATED APPLICATIONS

The entire disclosure of Japanese Patent Application No. 2023-181153 filed on Oct. 20, 2023 is incorporated herein by reference in its entirety.

### TECHNICAL FIELD

The present disclosure relates to an alternating current signal transfer apparatus and an alternating current apparatus.

### BACKGROUND ART

With the spread of electric vehicles and portable devices, the demand for non-contact power supply apparatuses that transmit alternating current power in a non-contact manner has been increasing.

Various methods of non-contact power supply have been proposed, but power transfer utilizing magnetic resonance, which is lighter in weight and has a longer power transfer distance than an electromagnetic induction system, is attracting attention (for example, refer to NPL 1). In the non-contact power supply method described in NPL 1, power is supplied by magnetic resonance between resonators, thus easing the accuracy requirements for the distance and position alignment between the coils. Further, since the apparatus does not use a magnetic material, the apparatus is lighter in weight.

By increasing the Q value of the coil used in the non-contact power supply apparatus, it is possible to achieve high-efficiency power transfer even with a low coupling coefficient (for example, refer to NPL 2). In the non-contact power supply method of NPL 2, the transmission characteristics change significantly when a coupling coefficient k changes due to a change in the distance between resonators, which requires adjustment due to the change of the transmission characteristics.

According to the filter theory of microwaves, it is possible to achieve no-reflection transfer by setting the external Q of the resonator in accordance with the coupling coefficient k (for example, refer to NPL 3).

The external Q can be set by dividing a capacitor used for the resonator and adjusting the capacitance value of each divided capacitor (for example, refer to PTL 1).

### CITATION LIST

### Patent Literature

### PTL 1

Japanese Patent No. 7039087

### PTL 2

Japanese Patent No. 6729919

### PTL 3

Japanese Patent No. 4835334

### PTL 4

Japanese Patent No. 7261517

### Non Patent Literature

### NPL 1

Wireless Power Transfer via Strongly Coupled Magnetic Resonances, Andre Kurs et. al, Science Vol. 317, Jul. 6, 2007

### NPL 2

T. Ohira “Angular expression of maximum power transfer efficiency in reciprocal two-port systems” Published in 2014 IEEE Wireless Power Transfer Conference, May 8-9 2014, INSPEC Accession Number: 14395324

### NPL 3

I. Awai and T. Ishizaki “Superiority of BPF theory for design of coupled resonator WPT systems” Asia-Pacific Microwave Conference 2011, pp. 1889-1892 (2011) INSPEC Accession Number: 12656013

### NPL 4

S. Y. R. Hui, W. Zhong and C. K. Lee “A Critical Review of Recent Progress in Mid-Range Wireless Power Transfer” IEEE Transactions on Power Electronics, vol. 29, no. 9, pp. 4500-4511 September 2014

### NPL 5

Takehiro Imura, “Wireless Power Transfer by Magnetic resonance,” Morikita Publishing, 2017, pp. 326-328

### SUMMARY OF INVENTION

In non-contact power supply that supplies power through magnetic resonance between resonators, the transmission characteristics significantly change when the coupling coefficient k is changed by the changes in the distance between the resonators. Accordingly, it is necessary to change the external Q value by changing the impedance of the power source or load connected to the resonator, and the value of the capacitor in accordance with the change in the coupling coefficient k. In non-contact power supply, it is often difficult to avoid a change in positional relationship between a power transmitting side coil and a power receiving-side coil. That is, each time power transfer is performed, the transmission characteristic changes with the non-constant coupling coefficient k value, and therefore it is necessary to change a circuit parameter such as a capacitance value.

Changing the circuit parameters entails exchanging or switching components, which makes the mechanism complicated, and requires additional control. In view of this, a method of restoring the coupling coefficient k by a mechanical method in a case where the positional relationship is changed has been proposed (for example, refer to PTL 2). The method in PTL 2, however, requires a mechanical operation and thus cannot respond instantaneously.

In view of this, it is desired to maintain high efficiency even when the positional relationship between resonators constituting a resonator pair is changed.

An object of the present invention is to provide a power transfer system and apparatus capable of maintaining high efficiency even when the positional relationship between resonators constituting a resonator pair is changed.

An alternating current signal transfer apparatus according to an embodiment of the present disclosure includes: a transmission line; a plurality of first phase shifters connected to the transmission line at a branching point; a plurality of resonator pairs each connected to each of the plurality of first phase shifters; and a plurality of second phase shifters each connected to each of the plurality of resonator pairs. The plurality of second phase shifters are connected at a connecting point.

The advantages and features provided by one or more embodiments of the invention will become more fully understood from the detailed description given hereinbelow and the appended drawings which are given by way of illustration only, and thus are not intended as a definition of the limits of the present invention:

### BRIEF DESCRIPTION OF DRAWINGS

FIG. 1 is a diagram illustrating a series resonance circuit;

FIG. 2 is a diagram illustrating a parallel resonance circuit;

FIG. 3 is a schematic diagram of a resonance power transfer circuit;

FIG. 4 is a diagram illustrating an S-S type resonance power transfer circuit;

FIG. 5 is a diagram illustrating reflection characteristics and transmission characteristics of the S-S type resonance power transfer circuit;

FIG. 6 is a diagram illustrating a complex reflectance and transmittance of the S-S type resonance power transfer circuit on a Smith chart;

FIG. 7 is a circuit diagram of a wireless power transfer apparatus using a plurality of resonator pairs;

FIG. 8 is a diagram illustrating an arrangement of resonator coils in a multi resonator configuration;

FIG. 9 is a diagram illustrating a reflectance in the multi resonator configuration on a Smith chart;

FIG. 10 is a diagram illustrating transmittance and reflectance in a case using a circuit of a multi resonator configuration including two circuits of a single resonator configuration that is flattest-matched at k=0.1;

FIG. 11 is a diagram illustrating transmission characteristics and reflection characteristics in a case where the phase shift angle on the power transmitting side is fixed at 20° and the phase shift angle on the power receiving side is changed;

FIG. 12 is a diagram illustrating reflection characteristics and transmission characteristics in four different circuit configurations;

FIG. 13A is a diagram illustrating a circuit using an S-S type resonance power transfer circuit in which a resistor is connected to a zero-ohm power source;

FIG. 13B is a diagram illustrating a circuit using an S-S type resonance power transfer circuit in which a capacitor is connected to the zero-ohm power source;

FIG. 13C is a diagram illustrating a circuit using an S-S type resonance power transfer circuit in which an inductor is connected to the zero-ohm power source;

FIG. 13D is a diagram illustrating a circuit using an S-S type resonance power transfer circuit in which an impedance line is connected to the zero-ohm power source;

FIG. 14 is a diagram illustrating an output power of a power source and a power consumption of a load in a case where an S-S type resonance power transfer circuit is used;

FIG. 15 is a diagram illustrating an output power of a power source and a power consumption of a load in a case where an S-P type resonance power transfer circuit is used;

FIG. 16 is a diagram illustrating an output power of a power source and a power consumption of a load in a case where a P-S type resonance power transfer circuit is used;

FIG. 17 is a diagram illustrating an output power of a power source and a power consumption of a load in a case where a P-P type resonance power transfer circuit is used;

FIG. 18 is a diagram illustrating an example of a phase shifter using an LC circuit;

FIG. 19 is a diagram illustrating an example of a multi resonator configuration using an open-ring resonator;

FIG. 20 is a diagram illustrating a transmittance and a reflectance in a case where transfer is performed using the open-ring resonator;

FIG. 21 is a diagram illustrating an influence of a power supply side line length on a transferred power in a single resonator configuration;

FIG. 22 is a diagram illustrating an influence of a power supply side line length on a transferred power in a multi resonator configuration; and

FIG. 23 is a diagram illustrating reflection characteristics and transmission characteristics of a multi-line configuration.

### DESCRIPTION OF EMBODIMENTS

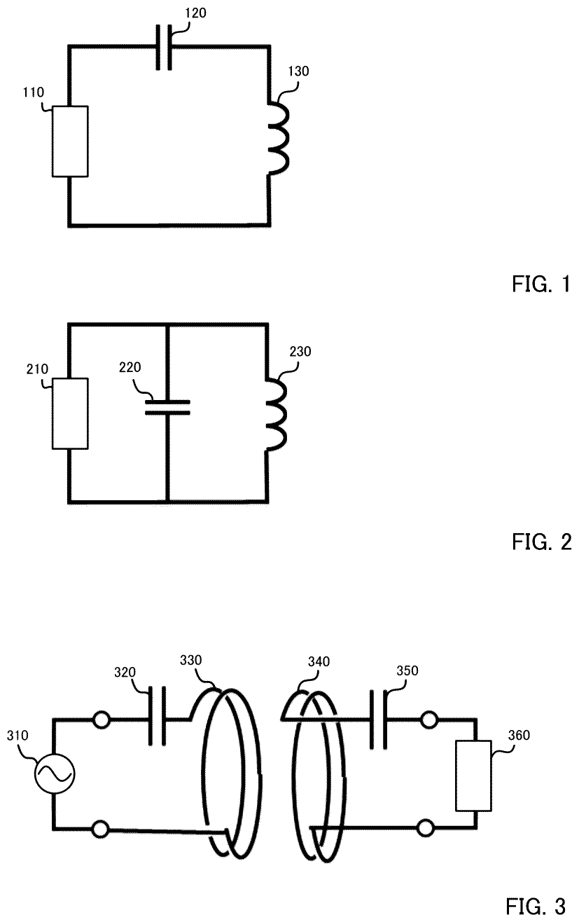

FIG. 1 is a diagram illustrating a series resonance circuit. The series resonance circuit is a circuit in which the load or power source 110 is connected to capacitor 120 and coil 130, which are connected in series.

FIG. 2 is a diagram illustrating a parallel resonance circuit. The parallel resonance circuit is a circuit in which a load or power source 210 is connected to capacitor 220 and coil 230, which are connected in parallel.

FIG. 3 is a schematic diagram of a resonance power transfer circuit. The resonance power transfer circuit includes alternating current power source (power source) 310, power transmitting side resonator capacitor 320, power transmitting side resonator coil (the power transmitting coil) 330, power receiving side resonator coil (power receiving coil) 340, power receiving side resonator capacitor 350, and load 360.

In FIG. 3, since power transmitting side resonator capacitor 320 and power transmitting side resonator coil 330 are connected in series, a power transmitting side circuit is called a series connection type (Series type, S type). Further, since power receiving side resonator capacitor 350 and power receiving side resonator coil 340 are connected in series, a receiving side circuit is also an S type. A resonance power transfer circuit in which the power transmitting side circuit is of an S type and the power receiving side circuit is of an S type is referred to as an S-S type resonance power transfer circuit.

Since power transfer is possible as long as there is electromagnetic coupling between the coils, power transfer is possible even using a parallel connection type resonator in addition to a series connection type resonator.

That is, for power transfer it is also possible to use an S-P type resonance power transfer circuit in which the power transmitting side circuit is of the S type and the power receiving side circuit is of a parallel connection type (parallel type, P type), a P-S type resonance power transfer circuit in which the power transmitting side circuit is of the P type and the power receiving side circuit is of the S type, and a P-P type resonance power transfer circuit in which the power transmitting side circuit is of the P type and the power receiving side circuit is of the P type, as well as the S-S type resonance power transfer circuit.

Generally, a resonance frequency f₀ of a resonator is represented by L₀ which represents an inductance of a coil, and C₀ which represents a capacitance value of a capacitor as follows.

$${f}_{0} = \frac{1}{2 π \sqrt{{L}_{0} {C}_{0}}} \qquad ( 1 )$$

[1]

In order to perform resonance power transfer, it is necessary to make the resonance frequencies between the power transmitting side of the resonator and the power receiving side of the resonator the same. Here, a characteristic impedance of the resonator will be referred to as a resonator impedance, which will be represented as Z_{K} and defined as follows.

$${Z}_{K} = \sqrt{\frac{{L}_{0}}{{C}_{0}}} \qquad ( 2 )$$

[2]

Here, when Zₛ represents the characteristic impedance of an external circuit of a signal line connected to the resonator, a power source or load connected to the signal line, and the like, Qₑ, which is the external Q, is defined as follows.

$$Case of series resonator {Q}_{e} = \frac{{Z}_{K}}{{Z}_{S}} \qquad ( 3 a )$$

$$Case of parallel resonator {Q}_{e} = \frac{{Z}_{S}}{{Z}_{K}} \qquad ( 3 b )$$

[3]

According to NPL 3, when the coupling coefficient k, the external Q of the power transmitting side resonator Q_{eT}, and the external Q of the power receiving side resonator Q_{eR} satisfy the relationship indicated by the following equation, it is possible to perform power transfer between a power transmitting resonator and a power receiving resonator without reflection. This will be referred to as “median matching”.

$${Q}_{eT} {Q}_{eR} = \frac{1}{{k}^{2}} \qquad ( 4 )$$

[4]

Further, according to NPL 3, the relationship represented by the following equation achieves the “maximally flat matching”, where a highly efficient frequency range spreads over the entire range between the resonance frequencies.

$${Q}_{eT} = \frac{1}{k} , {Q}_{eR} = \frac{1}{k} \qquad ( 5 )$$

[5]

In wireless power transfer, a power transfer signal usually uses a single frequency, and therefore it is not required to be highly efficient over a wide bandwidth. Since it suffices to perform optimization only for the case of using the resonance frequency of the resonator, it suffices to satisfy the easy condition of Equation (4).

However, according to NPL 3, in the case of the same coupling coefficient k, it is possible to minimize losses due to the internal resistance of a coil by satisfying the maximally flat matching condition of Equation (5). In addition, the maximally flat matching has a wider efficient frequency band, and thus advantageously provides a margin for errors of a circuit that occur when creating a resonator and peripheral circuits.

Accordingly, it can be said that it is effective to use a condition as close to the condition in Equation (5) as possible. The following description describes a condition where the maximally flat matching of Equation (5) is satisfied, but in the wireless power transfer, Equation (4) may be satisfied as described above.

When Equations (3a) or (3b) and (4) are combined, a coupling without reflection is represented by the following equations for each type of resonance power transfer circuit. Here, Z_{ST} is an output impedance of a power transmitting side power source, Z_{SR} is an input impedance of a power receiving side load, Z_{KT} is the resonator impedance of the power transmitting side resonator, and Z_{KR} is the resonator impedance of the power receiving side resonator.

$$S - S Type {Z}_{ST} = {k}^{2} \frac{{Z}_{KT} {Z}_{KR}}{{Z}_{SR}} \qquad ( 6 a )$$

$$S - P Type {Z}_{ST} = {k}^{2} \frac{{Z}_{KT}}{{Z}_{KR}} {Z}_{SR} \qquad ( 6 b )$$

$$P - S Type {Z}_{ST} = \frac{1}{{k}^{2}} \frac{{Z}_{KT}}{{Z}_{KR}} {Z}_{SR} \qquad ( 6 c )$$

$$P - P Type {Z}_{ST} = \frac{1}{{k}^{2}} \frac{{Z}_{KT} {Z}_{KR}}{{Z}_{SR}} \qquad ( 6 d )$$

[6]

The above-described equations indicate that in the case of using a coupling that does not cause reflection, the output impedance Z_{ST} of the power transmitting side power source becomes the input impedance Z_{SR} of the power receiving side load when passed through the resonator coupling, i.e., that the resonance power transfer circuit has a function of an impedance converter that varies with coupling coefficient k.

The following describes the S-S type resonance power transfer circuit as an example, but the same applies to other types as long as any of the impedance conversions in Equations (6b) to (6d) corresponding to the type is used.

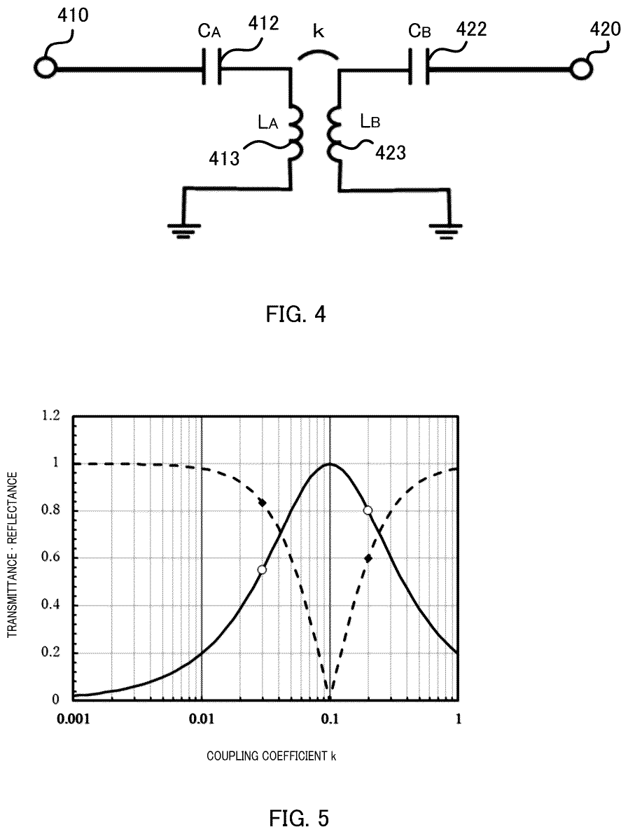

FIG. 4 is a diagram illustrating an S-S type resonance power transfer circuit. In a case where the resonator is constituted of power transmitting coil 413 and power receiving coil 423 each with an inductance of 1.591 μH, and capacitor 412 and capacitor 422 each with a capacitance of 159.1 pF, the resonance frequency of the resonator is 10 MHz, and the characteristic impedance Z_{K} of the resonator is 100Ω. Power transmitting coil 413 and power receiving coil 423 each with an inductance of 1.591 μH can be formed by winding a wire with a diameter of approximately 40 cm in a single turn.

In a case where the distance between power transmitting coil 413 and power receiving coil 423 is approximately equal to the diameter, the coupling coefficient k is approximately 0.05. The coupling coefficient k decreases approximately in inverse proportion to the cube of the distance. The range of the coupling coefficient k is determined in accordance with the application, but it is assumed to be approximately 0.01 to 0.5 in the present embodiment.

The output impedance of the line connected to terminal 410 of the power transmitting side resonator, e.g., the power source is referred to as Z_{T}, and the input impedance of the line connected to terminal 420 of the power receiving side resonator is referred to as Z_{R}. Here, when Z_{T}=10Ω and Z_{R}=10Ω, the characteristic impedance Z_{K} of the resonator is 100Ω, and thus Q_{eT}, which is an external Q on the power transmitting side, is 10, and, Q_{eR}, which is an external Q on the power receiving side, is also 10 according to Equation (3a). In this manner, Equation (5) holds when k=0.1, thus achieving the maximally flat matching.

FIG. 5 is a diagram illustrating reflection characteristics and transmission characteristics of the S-S type resonance power transfer circuit when the coupling coefficient k is changed with respect to a 10 MHz signal. In FIG. 5, a dotted line indicates the reflection characteristic (reflectance), and a solid line indicates the transmission characteristic (transmittance).

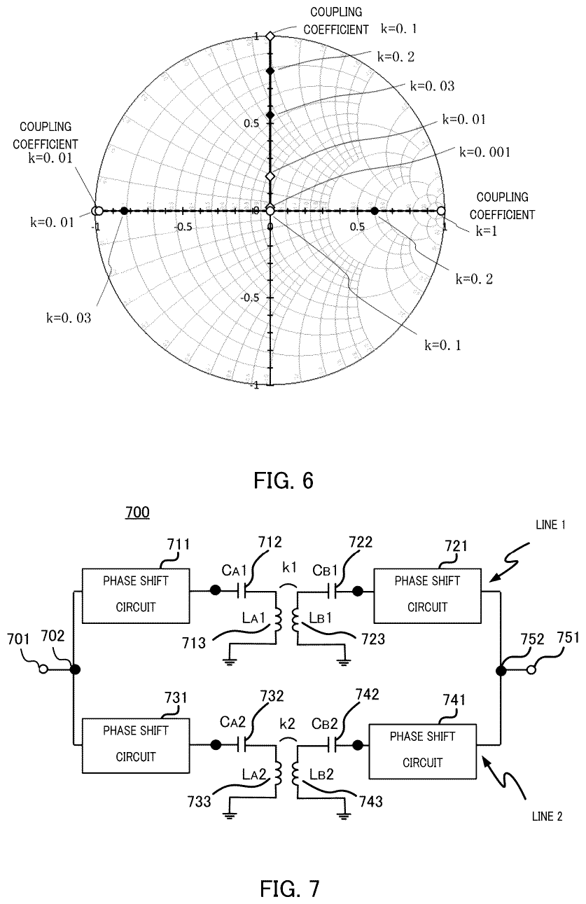

FIG. 6 is a diagram illustrating a complex reflectance and transmittance of the S-S type resonance power transfer circuit on a Smith chart. In FIG. 6, the reflectance of the S-S type resonance power transfer circuit is indicated by a white circle and a black circle, and the transmittance is indicated by a white rhombus and a black rhombus.

When the coupling coefficient k changes, the reflectance of the S-S type resonance power transfer circuit moves on a real axis from −1 to 1, and passes through the origin where the reflection is zero at k=0.1. On the other hand, the transmittance is delayed by 270°, i.e., it moves to a positive region on an imaginary axis, moves upward from the vicinity of the origin, reaches an outer peripheral section at k=0.1, and folds back.

As described above, a series resonator and/or a parallel resonator can be used as the resonator on the power transmitting side and the resonator on the power receiving side. As shown in Equations (6a) to (6d), when the resonator impedance and the coupling coefficient are determined, the combination of the optimal power source impedance and the optimal load impedance that results in zero reflection changes depending on the combination of resonator forms. By applying a resonator of a type having a value close to the resistance of the load and/or the impedance of the actual power source, it is possible to form a circuit with small loss.

In view of this, resonance power transfer circuits other than the S-S type resonance power transfer circuit, such as the S-P type, the P-S type, and the P-P type resonance power transfer circuits, are also examined.

Since the coupling coefficient k is determined by the distance between the coils constituting the resonator, the value of the coupling coefficient k does not change regardless of whether a series resonator or a parallel resonator is used. Further, the resonator impedance is the same value when the resonance frequency and the coil are the same. Equation (5) should be satisfied to satisfy the maximally flat matching, and as such, in the case of k=0.1, Q_{eT}=10 should be set on the power transmitting side regardless of the resonator type.

In a case where the characteristic impedance Z_{K} of the resonator is 100Ω, power transfer can be performed while satisfying the maximally flat matching by setting the characteristic impedance Z_{T} of the signal source to 10Ω according to the Equation (3a) when using the series resonator, and by setting the characteristic impedance Z_{T} of the signal source to 1000Ω according to the Equation (3b) when using the parallel resonator. The same applies to the load impedance on the power receiving side.

Regardless of the corresponding counterpart, in a case where the resonator is a series type, the reflectance is near −1 on the real axis of the Smith chart when k is small, and as k increases, k passes through the origin at k=0.1 and moves to the +1 side. In a case where the resonator is a parallel type, k is +1 when k is small, and as k increases, k passes through the origin at k=0.1 and moves to the −1 side.

Regarding the transmittance, in the case of the S-S type, with the phase delay of 270 degrees (the positive direction on the imaginary axis) at all times as illustrated in FIG. 6, it is near the origin when k is small, reaches the outer circumference of transmittance 1 at k=0.1, and returns to the origin again when k is larger than 0.1. The S-P type and S-S type have a phase delay of 0 degrees (the positive direction on the real axis), and change in the same manner. The P-P type has a phase delay of 90 degrees (the negative direction on the imaginary axis) and changes in the same manner.

The variation is as described above when the phase is included, but the reflectance and the transmittance are substantially the same for all types as the S-S type in FIG. 5 in terms of the absolute value.

### Multi Resonator Configuration

FIG. 7 is a circuit diagram of a wireless power transfer apparatus including a plurality of resonator pairs. Two S-S type resonance power transfer circuits are connected in parallel, and a phase shifter is installed in front of and behind each resonance power transfer circuit. Hereinafter, a configuration in which two resonator circuits are connected in parallel as illustrated in FIG. 7 will be referred to as a multi resonator configuration, and a configuration in which one resonator circuit is used as illustrated in FIG. 3 will be referred to as a single resonator configuration.

In FIG. 7, a plurality of lines connected in parallel to input terminal 701 are connected at branching point 702. The line refers to a series of circuits connected in series. For convenience, the line on the upper side in FIG. 7 will be referred to as line 1, and the line on the lower side will be referred to as line 2. Capacity C_{A}1 of capacitor 712, capacity C_{B}1 of capacitor 722, capacity C_{A}2 of capacitor 732, and capacity C_{B}2 of capacitor 742 constituting the respective resonator pairs are equal to each other, and inductance L_{A}1 of power transmitting coil 713, inductance L_{B}1 of power receiving coil 723, inductance L_{A}2 of power transmitting coil 733, and inductance L_{B}2 of power receiving coil 743 constituting the respective resonator pairs are equal to each other.

Input terminal 701 is connected to branching point 702. Branching point 702 branches into line 1 and line 2. Line 1 includes phase shifter 711, a resonator pair, and phase shifter 721. The resonator pair includes capacitor 712, power transmitting coil 713, power receiving coil 723, and capacitor 722.

One side of phase shifter 711 is connected to branching point 702. The other side of phase shifter 711 is connected to one side of capacitor 712. The other side of capacitor 712 is connected to one side of power transmitting coil 713. The other side of power transmitting coil 713 is grounded (connected to ground). Power transmitting coil 713 and power receiving coil 723 are coupled with a coupling coefficient k1.

One side of power receiving coil 723 is grounded. The other side of power receiving coil 723 is connected to one side of the capacitor 722. The other side of capacitor 722 is connected to one side of phase shifter 721. The other side of phase shifter 721 is connected to branching point (connecting point) 752. Branching point 752 is connected to an output terminal 751.

Line 2 includes phase shifter 731, a resonator pair, and phase shifter 741. The resonator pair includes the capacitor 732, the power transmitting coil 733, power receiving coil 743, and the capacitor 742.

One side of the phase shifter 731 is connected to branching point 702. The other side of the phase shifter 731 is connected to one side of the capacitor 732. The other side of the capacitor 732 is connected to one side of the power transmitting coil 733. The other side of the power transmitting coil 733 is grounded (connected to ground). The power transmitting coil 733 and power receiving coil 743 are coupled by a coupling coefficient k2.

One side of power receiving coil 743 is grounded. The other side of power receiving coil 743 is connected to one side of the capacitor 742. The other side of the capacitor 742 is connected to one side of the phase shifter 741. The other side of phase shifter 741 is connected to branching point 752.

Each phase shifter is input-output symmetric and has the same input impedance and output impedance. Thus, the phase shifter is a circuit that generates the same phase delay for signals input from either side.

### Coil in Multi Resonator Configuration

In a resonance transfer apparatus, an electrical influence due to a change in the positional relationship between the power transmitting and receiving coils appears as a change in the coupling coefficient. Specifically, the coupling coefficient varies depending on the distance between the power transmitting coil and the power receiving coil, and the relative orientations of the power transmitting coil and the power receiving coil. In the multi resonator configuration, the arrangement of the coils may be devised such that two coupling coefficients vary with the same value.

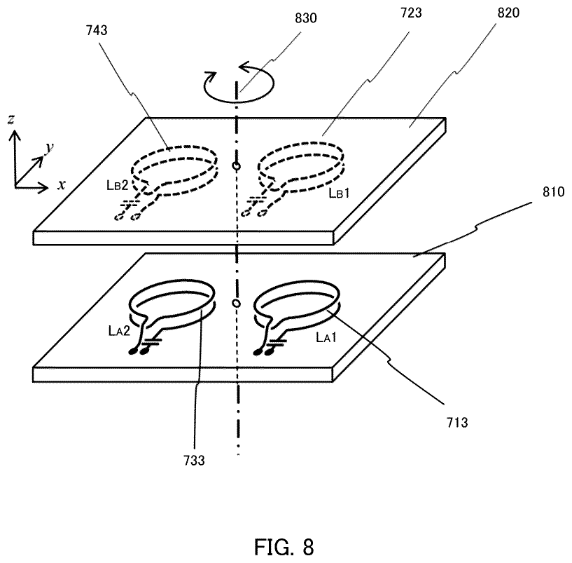

FIG. 8 is a diagram illustrating an arrangement of the resonator coils in the multi resonator configuration of FIG. 7. Power transmitting coil 713 and power transmitting coil 733 are disposed on a substrate 810 on the power transmitting side. Power receiving coil 723 and power receiving coil 743 are disposed on substrate 820 on the power receiving side. Power transmitting coil 713, power transmitting coil 733, power receiving coil 723, and power receiving coil 743 have the same configuration and the same characteristics.

Power transmitting coil 713 and power receiving coil 723 are coils of the resonator of line 1, and power transmitting coil 733 and power receiving coil 743 are coils of the resonator of line 2. When substrates 810 and 820 are disposed parallel to each other in the reference positions, power transmitting coil 713 and power receiving coil 723 are disposed to face each other, and power transmitting coil 733 and power receiving coil 743 are disposed to face each other.

Assuming power transfer from the ground side to the vehicle side, the ground side, i.e., the power transmitting side is fixed and therefore substrate 810 is fixed, while the vehicle side, i.e., the entire power receiving side is movable. When the vehicle stops on a flat road surface, substrates 810 and 820 are parallel to each other, although depending on the stopping position and orientation of the vehicle and the type of vehicle, substrate 820 may be moved in parallel in the x and y directions with respect to the reference position depending on the stopping position of the vehicle, and additionally, substrate 820 may be rotated around an axis perpendicular to the substrate depending on the direction in which the vehicle has stopped. However, when the parking direction of the vehicle is kept constant, no rotation occurs although substrate 820 is moved in parallel with the orientation fixed in the x, y, and z directions compared with the case where it is placed at the exactly opposite position.

Since power transmitting coil 713 and power transmitting coil 733 are disposed on substrate 810, and power receiving coil 723 and power receiving coil 743 are disposed on substrate 820, the distance between power transmitting coil 713 and power receiving coil 723 and the distance between power transmitting coil 733 and power receiving coil 743 are the same for the movement in the x, y, and z directions with the orientations of substrate 810 and substrate 820 fixed.

That is, the coupling coefficient k₁ of power transmitting coil 713 and power receiving coil 723 and the coupling coefficient k₂ of power transmitting coil 733 and power receiving coil 743 are the same value (k₁=k₂) although they vary. That is, in a case where the vehicle stop position is deviated to the front, rear, left, or right and the coupling state is changed, the coupling coefficients of the two resonator pairs are always the same value when the direction of the vehicle is kept constant.

Further, in a case where the coupling state changes due to a change in the vehicle height because of the vehicle weight, the distance between power transmitting coil 713 and power receiving coil 723 and the distance between power transmitting coil 733 and power receiving coil 743 remain the same although the distance in the z direction between substrate 810 and substrate 820 changes, and the value is the same although the coupling coefficient changes.

In addition, substrate 810 and substrate 820 may rotate about the common rotation axis 830, which results in a change in the coupling state. By disposing the position of the rotation axis at a point equidistant from two coils, the distance between power transmitting coil 713 and power receiving coil 723 and the distance between power transmitting coil 733 and power receiving coil 743 are the same even when substrates 810 and 820 rotate with respect to rotation axis 830. That is, the coupling coefficient k₁ of power transmitting coil 713 and power receiving coil 723 and the coupling coefficient k₂ of power transmitting coil 733 and power receiving coil 743 are the same value (k₁=k₂) although they vary.

As described above, in the resonator coupling circuit of FIG. 7, each coil has the same inductance, and each capacitor has the same capacitance, and, the coupling coefficient of each resonator has the same value although it varies.

By using a mechanical link or a cam mechanism, this relationship can be realized even with a more complicated multi resonator configuration.

Note that the way the coupling coefficient between coils varies depends on the shape of the coils. In view of this, desirably, each coil has the same shape because the coils with different shapes make the design complicated.

When the characteristic impedance of each line between branching point 702 and branching point 752 in FIG. 7 is 10Ω, the input impedance Z_{T0} at input terminal 701 matched at branching point 702 and the output impedance Z_{R0} at output terminal 751 matched at branching point 752 are each 5Ω, which is ½ of the characteristic impedance of each line. Hereinafter, in the plurality of line states, the line impedance will be expressed as the value for each single line in order to avoid confusion. Specifically, unless otherwise noted, the characteristic impedance before one line branches into two lines or after two lines are combined into one line is ½ of the line impedance. This ensures the impedance matching at branching points 702 and 752.

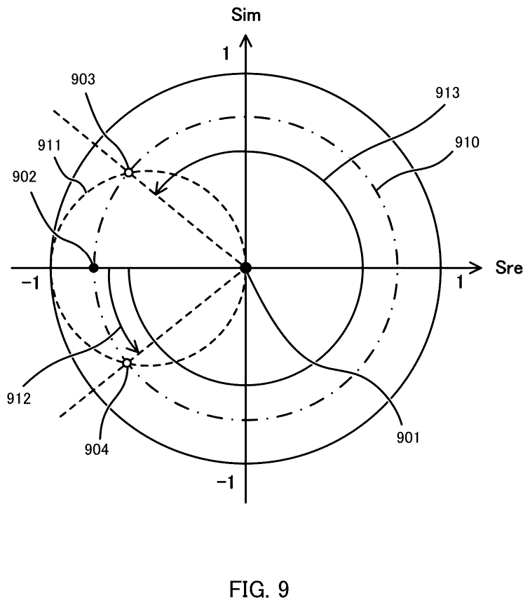

FIG. 9 is a diagram illustrating a reflectance on a Smith chart in a multi resonator configuration. In this case, the reference impedance is set to 10Ω. In the circuit shown in FIG. 7 described above, the case where the phase shift angles of the four phase shifters are all 0° is the same as the case with no phase shifter, and is therefore equivalent to the state where the two circuits connected in parallel in FIG. 4. That is, the k-value dependency of the reflectance as viewed from branching point 702 is the same as that in FIGS. 5 and 6 for line 1 side and line 2 side.

At k=0.1, the reflectance is zero and therefore the reflectance is at origin 901. That is, the signal is transferred from input terminal 701 to output terminal 751 with no reflection in either line 1 or line 2.

The following describes a case where k=0.013 is set by a change in the positional relationship of the resonator.

FIG. 7 is an S-S type resonance power transfer circuit with a series resonator on both the power transmitting side and the power receiving side, and the characteristic impedance Z_{K} of the resonator is 100Ω. Thus, considering Equations (3a) and (5), the maximally flat matching is established in a case where the output impedance Z_{ST} of the power transmitting side power source and the input impedance Z_{SR} of the power receiving side load are both 1.3Ω (Z_{TO}, Z_{SO} are half of 1.3Ω).

Assuming that the input impedance Z_{SR} of the power receiving side load is set to 1.3Ω, which establishes the maximally flat matching, and that the output impedance of the power transmitting side power source remains 10Ω, the reflectance of the resonator section as viewed from the power transmitting side is (−0.77, 0), i.e., point 902 in FIG. 9.

Here, the phase shift angle of the phase shifter 711 is changed. When the characteristic impedance of the phase shifter is set to 10Ω, which is the same as the reference impedance, the reflection coefficient moves on circumference 910 centered on the origin.

When the phase shift angle is changed by ±40° on the circumference 910, it intersects with equal-conductance circle 911 of 10Ω at two locations, points 903 and 904. The impedance represented by points 903 and 904 has real parts of 10Ω, and imaginary parts with the same absolute value but opposite signs.

That is, in the circuit in FIG. 7, when the phase shift angle of phase shifter 711 and the phase shift angle of phase shifter 731 are adjusted as described above, the real part of the composite impedance of the two lines as viewed from branching point 702 is 5Ω, and the imaginary part is 0. Therefore, even when the two lines branch at branching point 702, no reflection occurs at branching point 702 because the impedance matching is established.

Note that since the delay in the phase shifter can only take a positive value, changing the phase shift angle by ±X° means performing a phase shift of +X° (arrow 912) and a phase shift of (360−X)° (arrow 913).

In the case of a reflection wave, which passes twice the phase shifter, the change amount of the phase shift angle of the phase shifter may be (180−(X/2))° and +X/2°, half of +X°. That is, in the case of FIG. 7, the phase shift angle of the phase shifter 711 is Δ°, and the phase shift angle of the phase shifter 731 is (180−Δ)°, where Δ is 20.

Here, it is assumed that the impedance of the power receiving side line is already 1.3Ω. However, the impedance at branching point 752 is actually 10Ω, and therefore the same method as that on the power transmitting side is used to make it appear that the line with a characteristic impedance of 1.3Ω is connected. Specifically, the phase shift angle of phase shifter 721 is set to (180−Δ)°, the phase shift angle of phase shifter 741 to Δ°, and Δ to 20. Two phase shift angles are assigned to line 1 and line 2, and this selection is made such that the total phase delays between the power transmitting side and the power receiving side in line 1 and line 2 are the same value.

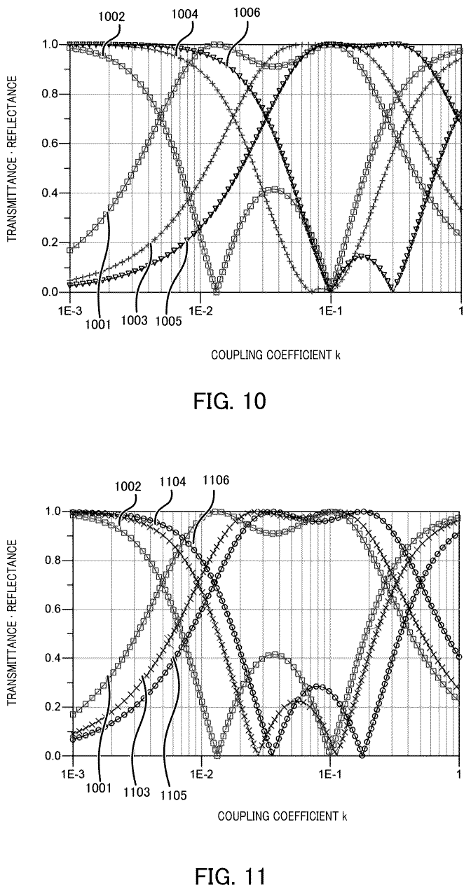

FIG. 10 is a diagram illustrating a transmittance and a reflectance in a case where a circuit of the multi resonator configuration using two single resonator configurations flattest-matched at k=0.1 is used. Line 1001 indicates the transmittance for Δ=20, line 1003 indicates the transmittance for Δ=40, line 1005 indicates the transmittance for Δ=60, line 1002 indicates the reflectance for Δ=20, line 1004 indicates the reflectance for Δ=40, and line 1006 indicates the reflectance for Δ=60. In each case the reflection at k=0.1 is zero, but another value of k with no reflection can be set to 0.013, 0.069, and 0.3.

Note that in FIG. 10, the phase shift amounts are the same for the power transmitting side and the power receiving side, but the phase shift amounts do not necessarily need to match.

FIG. 11 is a diagram illustrating transmission characteristics and reflection characteristics when the phase shift angle of the power transmitting side phase shifter is fixed at 20° and the phase shift angle of the receiving side phase shifter is varied.

Lines 1001 and 1002 are Δ=20 also on the power receiving side, and are therefore the same as FIG. 10. Line 1103 indicates the transmission characteristics for Δ=40 on the power receiving side, line 1105 indicates the transmission characteristics for Δ=60 on the power receiving side, line 1104 indicates the reflection characteristics for Δ=40 on the power receiving side, and line 1106 indicates the reflection characteristics for Δ=60 on the power receiving side.

In lines 1103 to 1106, there is no peak at k=0.1 set at the external Q of the single line, and impedance matching is achieved at two other k values although there is reflection, thus providing peaks in transmittance by setting the reflectance 0 at two k values.

In a case where two k values for the impedance matching are greatly different from each other, the peak of the transmittance is divided into two, whereas when the k values are close to each other, it is possible to achieve a substantially constant efficiency between the peaks. The two k values may coincide with each other. Even in a case where the two k values coincide with each other, the flatness of the efficiency near the peak increases and the high-efficiency range increases compared to the case of the single resonator configuration.

While the S-S type resonance power transfer circuit has been described above, the same applies to an S-P type resonance power transfer circuit, a P-S type resonance power transfer circuit, and a P-P type resonance power transfer circuit. In a case where the type of the resonator differs, it suffices to note the difference between equations (3a) and (3b) and the difference in phase delay in the resonator itself.

Table 1 shows the signal source impedance and the phase shift angle of the phase shifter, taking the above-mentioned points into consideration.

TABLE 1

| | | | Phase | Phase | Phase | Phase |
|---|---|---|---|---|---|---|
| | | | shifter | shifter | shifter | shifter |
| Type | Z_{T} (Ω) | Z_{R} (Ω) | 711 (deg) | 731 (deg) | 721 (deg) | 741 (deg) |
| S-S | k₀Z_{K} | k₀Z_{K} | ΔT | 180 − ΔT | 180 − ΔR | ΔR |
| S-P | k₀Z_{K} | Z_{K}/k₀ | 180 + ΔT | 180 − ΔT | 90 − ΔR | 90 + ΔR |
| P-S | Z_{K}/k₀ | k₀Z_{K} | 90 + ΔT | 90 − ΔT | 180 − ΔR | 180 + ΔR |
| P-P | Z_{K}/k₀ | Z_{K}/k₀ | 90 + ΔT | 90 − ΔT | 90 − ΔR | 90 + ΔR |

In Table 1, Δ_{T} is the phase shift angle of the phase shifter on the power transmitting side, Δ_{R} is the phase shift angle of the phase shifter on the power receiving side, Z_{K} is the resonator impedance, and k₀ is the set k value (which is 0.1 in the embodiment). When Δ_{T} and Δ_{R} are the same in each circuit format, almost the same reflection characteristics and transmission characteristics are obtained regardless of the circuit format.

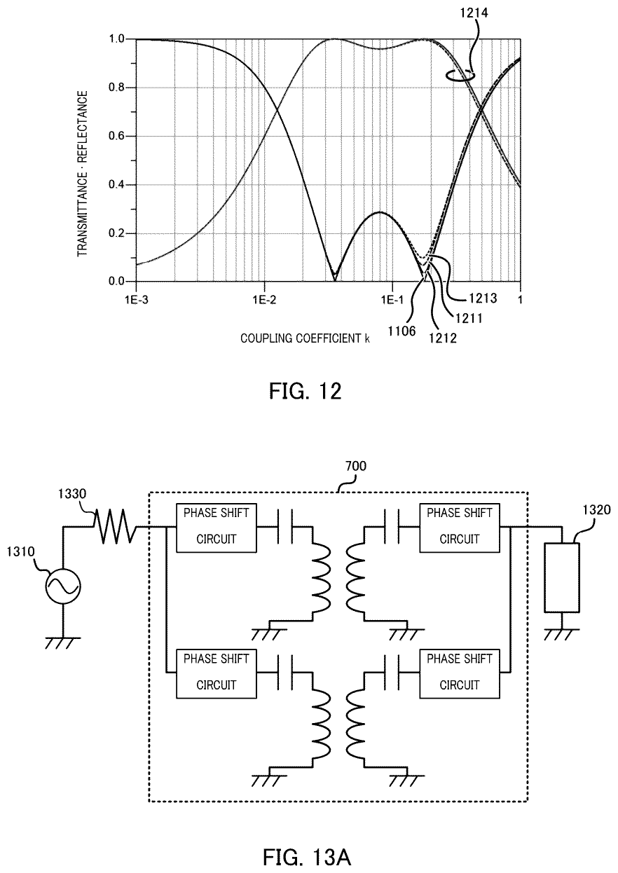

FIG. 12 is a diagram illustrating reflection characteristics and transmission characteristics in four different circuit configurations. FIG. 12 illustrates transmission characteristics and reflection characteristics in a case where the settings in Table 1 are made with the impedance of the power source or the load of a case using a parallel resonator set to 1000Ω, the impedance of the power source or the load of a case using a series resonator set to 10Ω, and the phase shift angles set to Δ_{T}=20° and Δ_{R}=60° such that all external Qs are 10.

Line 1214 indicates the transmission characteristics, and indicates substantially the same transmission characteristics for any of the S-S type resonance power transfer circuit, S-P type resonance power transfer circuit, P-S type resonance power transfer circuit, and P-P type resonance power transfer circuit. In FIG. 12, line 1106 indicates the reflection characteristics of the S-S type resonance power transfer circuit, line 1211 indicates the reflection characteristics of the P-P type resonance power transfer circuit, line 1212 indicates the reflection characteristics of the P-S type resonance power transfer circuit, and line 1213 indicates the reflection characteristics of the S-P type resonance power transfer circuit. Although there is a slight difference, it is possible to obtain almost the same characteristics.

### Use of Zero-Ohm Power Source

In the description so far, the output impedance of alternating current power source 310 connected to input terminal 701 and the input impedance of load 360 connected to output terminal 751 in the circuit having the multi resonator configuration illustrated in FIG. 7 are finite impedances. The reason for this is to eliminate reflection between the power source and the cable and between the cable and the load by setting the same impedance for the output impedance of the power source and the input impedance of the cable, and the output impedance of the cable and the input impedance of the load. Eliminating reflection is a common technique in microwave circuits.

In the case where the power supply has a finite output impedance, however, power consumption due to the impedance occurs within the power source, which reduces the power efficiency of the system as a whole while reflection at the resonator section can be prevented (for example, refer to NPL 4).

In order to avoid power consumption within the power source, a switching power supply composed of a lossless switch and a lossless filter such as an LC circuit is used. The switching power source, which is a voltage source whose output voltage is not changed by the load, has an output impedance of 0Ω and is called a zero-ohm power source.

The present embodiment performs power transfer and preferably does not entail power consumption within the power source, and it is therefore preferable to use a zero-ohm power source. When the output impedance of the power source is set to 0Ω, the power source and the line are not matched, which causes reflection.

In view of this, the following examines effects of the use of a zero-ohm power source, which does not establish impedance matching at the connection section to the power source.

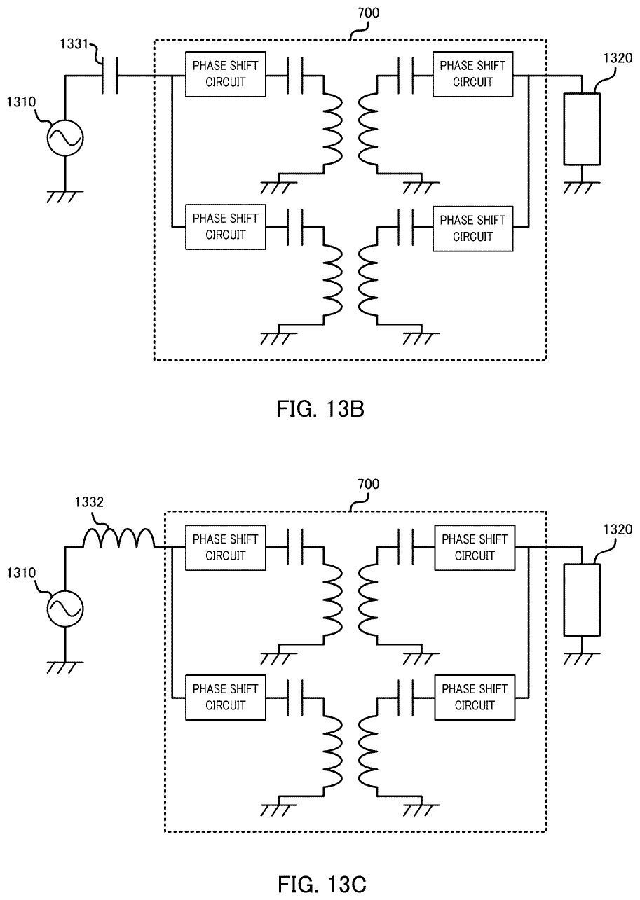

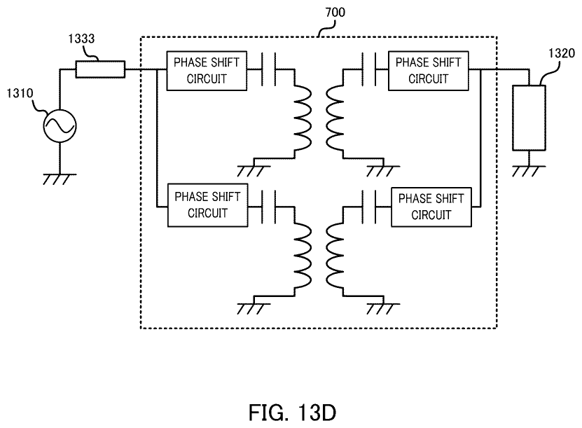

FIG. 13A is a diagram illustrating a circuit using an S-S type resonance power transfer circuit in which a resistor is inserted in series with a zero-ohm power source with a power source circuit with a normal finite resistance. The S-S type resonance power transfer circuit is the circuit shown in FIG. 7.

In a case of the setting for maximally flat matching at k=0.1, the impedance on the power source side and the impedance on the load side are 10 ohms. Further, the phase shift angle in the phase shifter is set to a value of Δ_{T}=20° and Δ_{R}=60° in the equations illustrated in Table 1.

Line 1106 and line 1214 in FIG. 12 indicate the reflection characteristics and the transmission characteristics, respectively, in a case of using a power source with a finite output impedance that establishes matching with the input impedance of the resonator circuit. Referring to line 1106 indicating the reflection characteristic, it is understood that the reflection is zero at k=0.035 and k=0.170.

Here, assuming power transfer, alternating current power source 1310 in FIG. 13A is a zero-ohm power source with an output effective voltage of 100 V, and resistor 1330 is 5Ω.

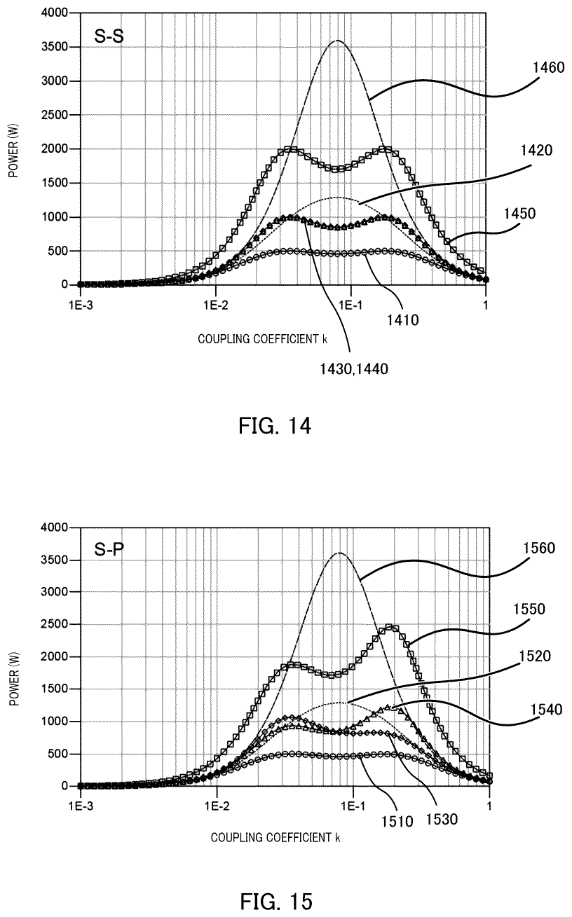

FIG. 14 is a diagram illustrating an output power of zero-ohm power source 1310 and a power consumption of a load in a case where an S-S type resonance power transfer circuit is used.

In this case, as illustrated in FIG. 12, the impedances are matched at k=0.035 and k=0.170, and the load as viewed from zero-ohm power source 1310 is 10Ω because it is a series connection of resistor 1330 and resonance power transfer circuit 700 with a multi resonator configuration. Since the output effective voltage of zero-ohm power source 1310 is 100 V, the supply power is (100 V)²/10Ω, or 1000 W.

In FIG. 14, line 1410 indicates the power consumed by load 1320 when resistor 1330 with a resistance of 5Ω is inserted in series with the output of zero-ohm power source 1310, and line 1420 indicates the power output by zero-ohm power source 1310 in that case. The difference is the power consumed by resistor 1330. This is a power loss in the impedance-matched power source, and the objective here is to eliminate this.

At k=0.035 and 0.17 where the reflection is zero, the 1000 W output power of zero-ohm power source 1310 is consumed by 500 W by resistor 1330, and 500 W by load 1320.

That is, the loss is 50% or the efficiency is 50%. An efficiency of 50% is hardly considered efficient power transfer.

In order to reduce losses due to consumption at resistor 1330, it is necessary to reduce the resistance value of resistor 1330 connected in series to zero-ohm power source 1310. When the resistance value of resistor 1330 is 0Ω, no loss due to resistor 1330 occurs.

When the resistance value of resistor 1330 is reduced, the two k values at which the power output by zero-ohm power source 1310 peaks approach each other and converge into one when the resistance value is 0Ω. Line 1460 in FIG. 14 indicates the power output by zero-ohm power source 1310 when resistor 1330 is 0Ω.

In this case, the power output by zero-ohm power source 1310 greatly varies depending on the k value even when the voltage of zero-ohm power source 1310 is fixed. That is, in order to keep the power supplied to load 1320 constant, it is necessary to change the voltage supplied by zero-ohm power source 1310 in accordance with the k value, which is extra work. Further, this involves changing the current value, which requires the addition of extra capability to the power source.

FIG. 13B is a diagram illustrating a circuit in which capacitor 1331 is connected instead of resistor 1330 in FIG. 13A. FIG. 13C is a diagram illustrating a circuit in which inductor 1332 is connected instead of resistor 1330 in FIG. 13A. FIG. 13D is a diagram illustrating a circuit in which impedance line 1333 is connected instead of resistor 1330 in FIG. 13A. Capacitor 1331, inductor 1332, and impedance line 1333 do not cause any loss even when current flows.

In a case where capacitor 1331 or inductor 1332 is connected, the reactance value, which is the imaginary part of the impedance, is set to 5Ω, which is the same value as the resistance value of resistor 1330.

Specifically, in a case where capacitor 1331 is connected instead of resistor 1330, a capacitor with a capacitance of 3.183 nF is connected. In a case where inductor 1332 is connected instead of resistor 1330, an inductor with an inductance of 79.6 nH is connected.

Further, in a case where impedance line 1333 is connected instead of resistor 1330, an impedance line with a characteristic impedance of 5Ω and a line length of ⅛ of the wavelength (with a phase shift angle of 45°) is connected. In this manner, the k-value at which the reflection is zero is the same as that of the case where resistor 1330 of FIG. 13A is set to 5Ω.

In FIG. 14, line 1430 indicates the power consumed by load 1320 of FIG. 13B, and line 1440 indicates the power consumed by load 1320 of FIG. 13C, and, both lines indicate exactly the same characteristic. In FIG. 14, line 1450 indicates the power consumed by load 1320 of FIG. 13D.

The peaks of the power consumption of lines 1430, 1440, and 1450 are at k=0.035 and k=0.17, and the peak powers are 1000 W in lines 1430 and 1440, and 2000 W in line 1450.

While the peak power values are different from each other, there are peaks of the power consumption of load 1320 at k=0.035 and k=0.17, and the power consumption of load 1320 does not vary significantly for k values satisfying 0.035<k<0.17 even when the k value varies. In these cases, the power consumption of the load and the output power of the power source are the same, and it is therefore not necessary to generate power over a wide range as zero-ohm power source 1310.

While the case where the S-S type resonance power transfer circuit is used has been described above, the same applies to the S-P type resonance power transfer circuit, P-S type resonance power transfer circuit, and P-P type resonance power transfer circuit.

First, in the same manner as in the S-S type resonance power transfer circuit, the impedance of the load is set such that the load is flattest-matched at k=0.1 for each type of resonance power transfer circuit. The impedance to be set is 10Ω for the P-S type resonance power transfer circuit with an S-type load side resonator, and 1000Ω for the S-P type resonance power transfer circuit or the P-P type resonance power transfer circuit with a P-type load side resonator. In FIGS. 13A, 13B, 13C, and 13D, resonance power transfer circuit 700 is illustrated as the S-S type, but the following description assumes that this part is appropriately changed to a resonant transfer circuit of a corresponding type.

In the case of the S-P type resonance power transfer circuit, the resistor 1330 connected in series to zero-ohm power source 1310 to achieve impedance matching between the power source and the resonance power transfer circuit is 5Ω, and therefore it suffices to uses the same capacitance, inductance, or impedance line as those of the S-S type resonance power transfer circuit for capacitor 1331, inductor 1332, or impedance line 1333.

In the case of the P-S type resonance power transfer circuit or the P-P type resonance power transfer circuit, the resistance value of resistor 1330 connected in series to zero-ohm power source 1310 for matching is 500Ω, and therefore it suffices that the capacitance of capacitor 1331 is 31.83 pF, the inductance of inductor 1332 is 7960 nH, the characteristic impedance of impedance line 1333 is 500Ω, and the line length is ⅛ of the wavelength (the phase shift angle is 45°).

FIG. 15 is a diagram illustrating an output power of a power source and power consumption of a load in a case where an S-P type resonance power transfer circuit is used.

In FIG. 15, line 1510 indicates the power consumed by load 1320 in a case where 5Ω resistor 1330 is inserted in series with the output of zero-ohm power source 1310 in order to achieve impedance matching at the power source section, and line 1520 indicates the power that is output by the power source in that case. The difference is the power consumed by resistor 1330. Line 1560 indicates the power consumed by load 1320 in a case where the resistance value of resistor 1330 is 0Ω.

Line 1530 indicates the power consumed by load 1320 of FIG. 13B in a case where resistor 1330 is replaced with capacitor 1331. Line 1540 indicates the power consumed by load 1320 of FIG. 13C in a case where resistor 1330 is replaced with inductor 1332. Line 1550 indicates the power consumed by load 1320 of FIG. 13D in a case where resistor 1330 is replaced with impedance line 1333.

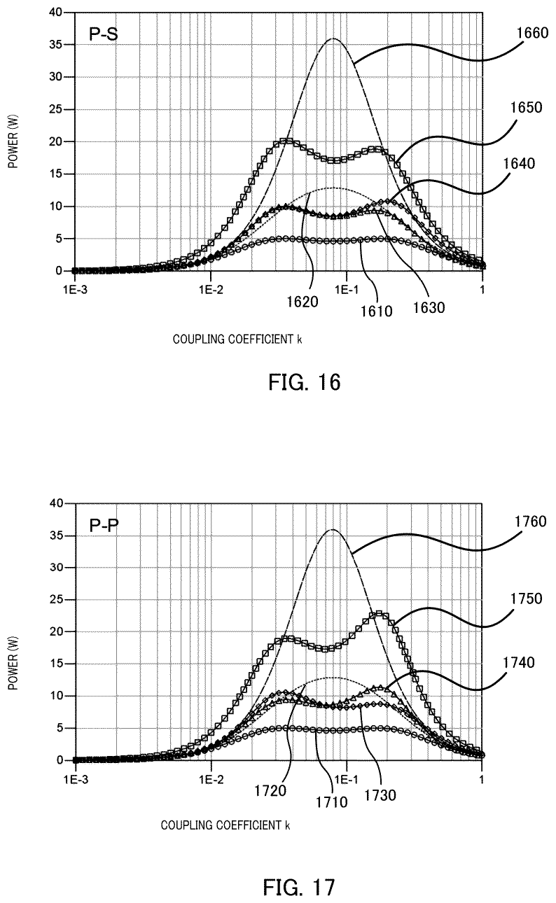

FIG. 16 is a diagram illustrating an output power of a power source and power consumption of a load in a case where a P-S type resonance power transfer circuit is used.

In FIG. 16, line 1610 indicates the power consumed by the load in a case where 500Ω resistor 1330 is inserted in series with the output of zero-ohm power source 1310 in order to achieve impedance matching at the power source section, and line 1620 indicates the power that is output by the power source in that case. Line 1660 indicates the power consumed by load 1320 in a case where the resistance value of resistor 1330 is 0Ω.

Line 1630 indicates the power consumed by load 1320 of FIG. 13B in a case where resistor 1330 is replaced with capacitor 1331. Line 1640 indicates the power consumed by load 1320 of FIG. 13C in a case where resistor 1330 is replaced with inductor 1332. Line 1650 indicates the power consumed by load 1320 of FIG. 13D in a case where resistor 1330 is replaced with impedance line 1333.

FIG. 17 is a diagram illustrating an output power of a power source and power consumption of a load in a case where a P-P type resonance power transfer circuit is used.

In FIG. 17, line 1710 indicates the power consumed by the load in a case where 500Ω resistor 1330 is inserted in series with the output of zero-ohm power source 1310 in order to achieve impedance matching at the power source section, and line 1720 indicates the power that is output by the power source in that case. Line 1760 indicates the power consumed by load 1320 in a case where the resistance value of resistor 1330 is 0Ω.

Line 1730 indicates the power consumed by load 1320 of FIG. 13B in a case where resistor 1330 is replaced with capacitor 1331. Line 1740 indicates the power consumed by load 1320 of FIG. 13C in a case where resistor 1330 is replaced with inductor 1332. Line 1750 indicates the power consumed by load 1320 of FIG. 13D in a case where resistor 1330 is replaced with impedance line 1333.

Referring to FIGS. 15 to 17, the output power in the S-P type resonance power transfer circuit is substantially the same as that in the S-S type resonance power transfer circuit, while the output power of the P-S type resonance power transfer circuit and the P-P type resonance power transfer circuit is approximately 1/100 of the output power of the S-S type resonance power transfer circuit. This is because the input impedance to the resonator is set to 5Ω in the S type and 500Ω in the P type in order to match the external Q with the k value. On the other hand, in the increase or decrease with respect to the fluctuation in the k value, there are peaks at k=0.035 and k=0.17 in all cases, and the variation there between is small. In a case where a predetermined impedance line is installed, a predetermined inductor is installed, or a predetermined capacitor is installed at the power source section, there is no loss due to the power source resistance, and therefore all the power supplied from the power source is consumed by the load, thus suppressing the power fluctuation due to the k-value change.

According to FIGS. 15 to 17, it is possible to transfer substantially constant power with no loss even when the coupling coefficient is varied by disposing an appropriate lossless component as with the S-S type.

### Phase Shifter Using LC

In the description so far, the phase shifter is analyzed using an impedance line for the convenience of simulation. However, in a case where the MHz band is used, the impedance line is physically very long, and therefore it is common to form the phase shifter using individual components such as a capacitor and an inductor.

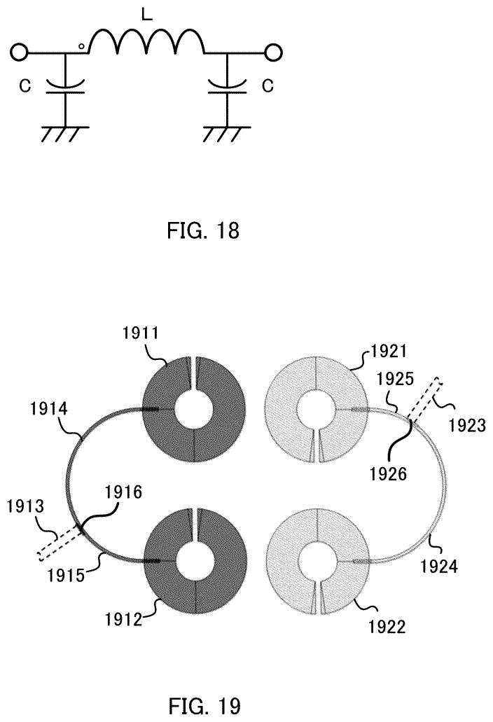

FIG. 18 is a diagram illustrating an example of a phase shifter using an LC circuit.

Table 2 shows capacitance value C and inductance value L used in the phase shifter in FIG. 13 in the case of performing a phase shift of 10° to 90° for a signal of 10 MHz with a characteristic impedance of 10Ω or 1000Ω. The case of 90° or greater can be handled by making the circuit multistage.

TABLE 2

| | Characteristic impedance | |
|---|---|---|
| Phase shift angle | 10 Ω | 1000 Ω |

| (degree) | C (pF) | L (nH) | C (pF) | L (μH) |
|---|---|---|---|---|
| 10 | 139 | 27.5 | 1.39 | 2.75 |
| 20 | 281 | 54.3 | 2.81 | 5.43 |
| 30 | 427 | 79.4 | 4.27 | 7.94 |
| 40 | 580 | 102.3 | 5.8 | 10.23 |
| 50 | 743 | 121.6 | 7.43 | 12.16 |
| 60 | 918 | 137.8 | 9.18 | 13.78 |
| 70 | 1115 | 149.4 | 11.15 | 14.94 |
| 80 | 1337 | 156.5 | 13.37 | 15.65 |
| 90 | 1590 | 159.1 | 15.9 | 15.91 |

### Open-Ring Resonator

In the foregoing description, an LC resonator is used as the resonator, and power is transferred by using electromagnetic coupling with the mutual inductance between the coils. However, it is difficult for the LC resonator to handle the higher frequency, and as such an open-ring resonator is used (for example, PTL 3).

The open-ring resonator is formed by folding a half-wavelength antenna into a ring shape and bringing both ends close to each other. Non-contact power transfer through electromagnetic coupling is performed with the open-ring resonator placed in close proximity. The external Q of the open-ring resonator is determined by the characteristic impedance of the line itself, the characteristic impedance of the input and output signal line, and the position where the signal line is connected in the ring (PTL 4). The coupling coefficient is determined by the relative orientation of the cutout section, the positional relationship and distance between the two open-ring resonators, and the like.

FIG. 19 is a diagram illustrating an example of a multi resonator configuration using an open-ring resonator. Open-ring resonator 1911 and open-ring resonator 1912 are formed on one printed substrate, and open-ring resonator 1921 and open-ring resonator 1922 are formed on another printed circuit board. Open-ring resonator 1911 and open-ring resonator 1921, and open-ring resonator 1912 and open-ring resonator 1922 are disposed close to and facing each other, and output the power input from input line 1913 to output line 1923 in a non-contact manner.

FIG. 19 illustrates the metal patterns of each surface in a shifted manner for the purpose of easy understanding, but open-ring resonator 1911 and open-ring resonator 1921, and open-ring resonator 1912 and open-ring resonator 1922 are disposed so as to overlap with each other in the vertical direction. In this manner, when the substrate equipped with the open-ring resonator is separated in parallel or shifted in the lateral direction, the relative positional relationship between open-ring resonators 1911 and 1921, and 1912 and 1922 is the same, and therefore the coupling coefficients in both resonator sets are equal to each other.

Each open-ring resonator uses gold wiring with a thickness of 1 μm, an outer diameter of 15 mm, a circumference width of 5 mm, and a resonance frequency of 2.45 GHz, and is formed on a printed substrate with a thickness of 1 mm and a relative dielectric constant of 4.2. Microstrip lines 1914, 1915, 1924, and 1925 with a characteristic impedance of 100Ω are each connected to the open-ring resonators at a location 90° from the midpoint of the ring.

Microstrip line 1914 and microstrip line 1915 from input line 1913 to each open-ring resonator attachment section, and microstrip line 1924 and microstrip line 1925 from each open ring attachment section to output line 1923 constitute a phase shifter. Input line 1913 and output line 1923 have a characteristic impedance of 50Ω.

Hereinafter, a configuration in which two resonator pairs are connected in parallel to each other will be referred to as a multi resonator configuration, and a configuration in which one resonator pair is used will be referred to as a single resonator configuration, as described in FIG. 19. Although the characteristic impedance of the input and output line with the single resonator configuration is set to 100Ω, the characteristic impedances of input line 1913 and output line 1923 are matched by being set to 50Ω since the two resonator pairs are connected in parallel to input line 1913 and output line 1923 in the multi resonator configuration.

When the distance between print substrates where the open-ring resonator is formed, i.e., the open-ring resonator distance, is changed, the coupling coefficient between the rings decreases as the open-ring resonator distance increases. On the other hand, the connection of the wiring to the open-ring resonator is fixed at 90° from the midpoint of the ring circumference, and thus the value of the external Q is fixed.

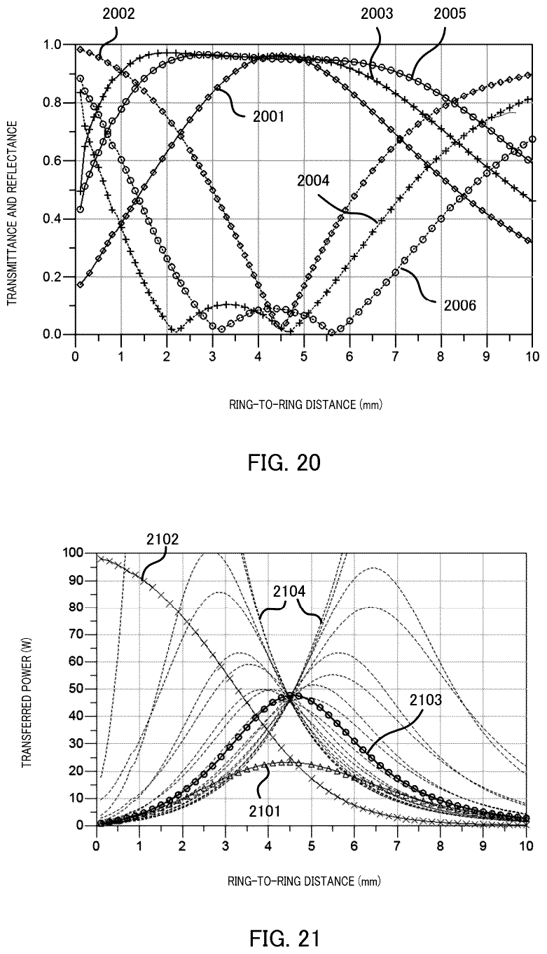

FIG. 20 is a diagram illustrating a transmittance and a reflectance of transmission using the above-described open-ring resonator.

Line 2001 and line 2002 indicate the transmittance and the reflectance, respectively, of a single resonator configuration. A ring-to-ring distance of 4.5 mm establishes the maximum flat matching, resulting in a zero reflectance and a maximum transmittance. The transmittance is not 1 due to the loss caused by the skin effect of the gold wiring in the open-ring resonator. In the case of the single resonator configuration, the transmittance is 90% or more in a range of approximately 1.5 mm from ring-to-ring distances of 3.5 mm to 5 mm.

On the other hand, line 2003 and line 2004 indicate the transmittance and the reflectance, respectively, of a case where in the multi resonator configuration (FIG. 19), the phase shift angle of the microstrip line 1915 and the microstrip line 1925 is set to 55°, and the phase shift angle of the microstrip line 1914 and the microstrip line 1924 is set to 125°.

Since reflection at a ring-to-ring distance of 2.2 mm, in addition to a ring-to-ring distance of 4.5 mm as in the single resonator configuration, is suppressed, a transmittance of 90% is achieved in a range of 5.5 mm from 1 mm to 6.5 mm of the ring-to-ring distance.

Further, line 2005 and line 2006 indicate the transmittance and the reflectance, respectively, of a case where the phase shift angle of microstrip line 1925 on the power receiving side is set to 35° and the phase shift angle of microstrip line 1924 is set to 145° without changing the phase shift angles of microstrip line 1914 and microstrip line 1915 on the power transmitting side.

As in the case of the resonator using the coil in FIGS. 13A to 13D, the ring-to-ring distance at which the reflection is zero is set to two distances different from the set distance of 4.5 mm for the maximally flat matching in the single line. By adjusting the phase shift angles of the wiring connected to the open-ring resonator on the power transmitting side and the power receiving side, it is possible to set two ring-to-ring distances for the zero reflectance and it is possible to maintain a low reflectance and a high transmittance at distances between the two ring-to-ring distances.

A case has been described so far in which the resistance of the power source is a finite value of 50Ω, which is the same as the impedance of the transmitting and receiving line. For high efficiency in power transfer, it is preferable to use a zero-ohm power source. Even in a case where the open-ring resonator is used, it is possible to take measures against the dependency on the k value of the reflectance by generating the same reactance by using a lossless capacitor, an inductor, or a characteristic impedance line in the same manner as in the case of the LC resonator.

First, the following considers a case in which a power source with an output impedance of 0Ω is connected to input line 1913 via 100Ω resistor in the single resonator configuration and via 50Ω resistor in the multi resonator configuration, such that the impedance matching is established. This is a condition in which impedance matching is achieved at the power source section.

In the case of the multi resonator configuration, the phase shift angle of the wiring is 55° and 125° on the power transmitting side, and 35° and 145° on the power receiving side. Line 2005 and line 2006 indicate the transmittance and the reflectance in this case, respectively. As described in FIG. 20, in the single resonator configuration, the reflectance is 0 at a ring-to-ring distance of 4.5 mm, and in the multi resonator configuration, the reflectance is 0 at ring-to-ring distances of 3.2 mm and 5.6 mm, thus achieving impedance matching between the power source and the load.

FIG. 21 is a diagram illustrating an influence of the power transmitting side line length on the transfer power in a single resonator configuration. Line 2101 indicates the power consumption of the load, and line 2102 indicates the power consumption of the power source resistance.

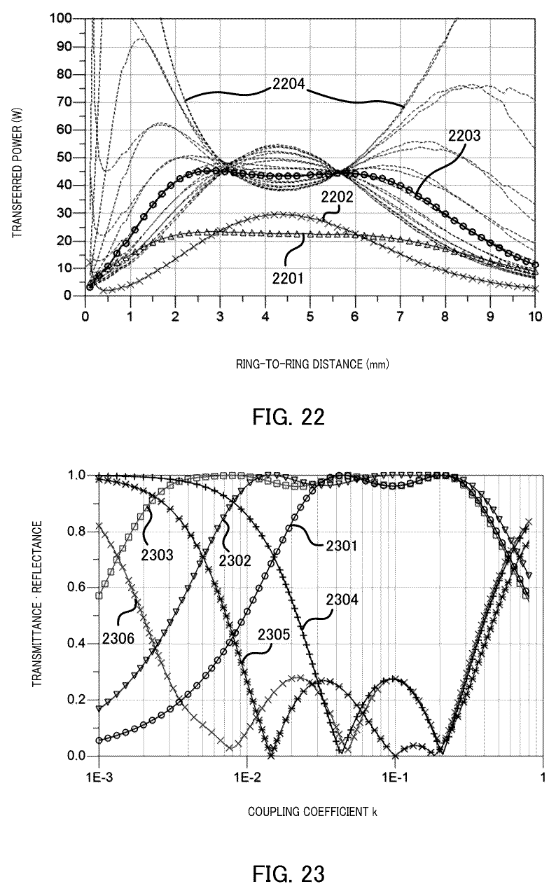

FIG. 22 is a diagram illustrating an influence of the power transmitting side line length on the transfer power in the multi resonator configuration. Line 2201 indicates the power consumption of the load, and line 2202 indicates the power consumption of the power source resistance.

In both the single resonator configuration and the multi resonator configuration, the power consumption of the load is approximately 25 W at a ring-to-ring distance where the reflectance is zero, and the power consumption at the power source resistance is approximately 25 W. It is not exactly 25 W because of losses at the open ring section.

As a result, half of the 50 W total power consumption as viewed from the power source is shared by the power resistor and the load portion. This indicates that half of the input power is wasted by the resistance of the power source despite the condition of no reflection. In this state, changing the signal line length in the single resonator configuration or the line lengths of the input line 1913 and the output line 1923 in the multi resonator configuration does not affect the transfer power because there is no reflection.

The following considers the case of FIG. 13B. Resonance power transfer circuit 700 is a circuit using the open-ring resonator illustrated in FIG. 19. The capacitance value is a value that has the same impedance value as the matching resistance, and is 0.65 pF in the single resonator configuration and 1.3 pF in the multi resonator configuration. Capacitor 1331 is installed between the output of the zero-ohm power source and branching point 1916, which is the input of the resonator pair.

In this case, line 2103 in FIG. 21 and line 2203 in FIG. 22 indicate the ring-to-ring distance dependency of the power consumption of the load of the single resonator configuration and the multi resonator configuration, respectively. Note that the cable length on the power source side is set to zero.

As compared to line 2101 and line 2201 representing the case where the matching resistance is inserted, it is understood that they both consume almost double power at the load. This indicates that the power is consumed by the load with no loss. In the case of the multi resonator configuration, the power is substantially constant at a ring-to-ring distance of about 3 mm to 6 mm and is consumed by the load with no loss.

In a microwave circuit, equipment is commonly connected to other equipment using an impedance line because of the short wavelength. In a case where the power source and the resonator, the resonator and the load, and the equipment and the cable are impedance-matched, there is no reflection wave, and therefore the change in the cable length causes no problem. However, when a zero-ohm power source or a reactance circuit is connected, reflection occurs at the cable and the power source, and the cable and the reactance circuit section, which adversely affects the circuit operation. In view of this, lines 2104 and 2204 indicate the power consumption of the load in a case where an impedance line is connected as input line 1913 between the portion where the capacitor is connected to the zero-ohm power source and branching point 1916 that serves as the input section of the open-ring resonator, and the length of the impedance line is changed as the phase shift angle from 0° to 360° at intervals of 10°. Since input line 1913 has no loss, the power consumption of the load is the power supplied by the power source.

In both configurations, the power consumption of the load varies depending on the line length except for the ring-to-ring distance at which the reflectance is zero. Especially in the single resonator configuration, the variation due to deviation from the impedance-matched distance is significant, and therefore precise adjustment of the line length is required.

On the other hand, in the multi resonator configuration, the change amount is kept low between the two ring-to-ring distances where matching is established. That is, the multi resonator configuration can transfer a constant power over a wide range of ring-to-ring distances and also has high resistance to fluctuation in wiring length. Note that, on the power receiving side, impedance matching with the load is established, and therefore there is no dependency of the signal line on the line length.

### Branching of Three or More Lines

In the above description, a case has been described in which the line to the power source or the load is separated into two, but the number of the separation is not limited to two. A wireless power transfer apparatus including three or more resonator pairs may be adopted. Even in a case of the separation into three or more lines, a first phase shifter is connected at a branching point for each line, a resonator pair including a power transmitting coil and a power receiving coil is connected to each phase shifter, a second phase shifter is connected to each resonator pair, and each second phase shifter is connected to a branching point (connecting point). Further, even in a case where the lines are divided into three or more, the coupling coefficient of each resonator pair is the same value. The phase shift angle in the case where the separation into three or more lines is difficult to obtain geometrically as in the case of the separation into two lines, but can be obtained with high accuracy by using an optimization program of a circuit simulator or the like.

FIG. 23 illustrates reflection characteristics and transmission characteristics of a case where the line is divided into two, three, and four in the S-S resonance power transfer circuit described in FIGS. 10 and 11 used, and the phase shift amounts of all the phase shifters on the power transmitting side and the power receiving side are determined using the optimization program so as to minimize reflection within a certain k value range in each case. The targeted range of the k value in optimization and the obtained phase shift angle are shown in Table 3. In the case of two lines or three lines, the line impedance of the single line is set to 10Ω so as to achieve the maximally flat matching at k=0.1, whereas in the case of four lines, the lower k value is also important, and therefore the line impedance is set to 1Ω so as to achieve the maximally flat matching at k=0.01.

TABLE 3

| Number of divided | Two lines | | Three lines | | Four lines | |
|---|---|---|---|---|---|---|
| lines | | | | | | |
| Optimization range | 0.03 to 0.3 | | 0.01 to 0.3 | | 0.003 to 0.3 | |
| of k value | | | | | | |
| Line impedance | 10 Ω | | 10 Ω | | 1 Ω | |
| Phase shift angle of | Input | Output | Input | Output | Input | Output |
| phase shifter (degree) | side | side | side | side | side | side |
| First line | 64.3 | 156.6 | 16.7 | 163.3 | 56.4 | 93.9 |
| Second line | 115.7 | 23.4 | 163.3 | 16.7 | 95.9 | 24.4 |
| Third line | | | 90 | 90 | 4.2 | 161.7 |
| Fourth line | | | | | 85.8 | 86.7 |

Lines 2301 and 2304 indicate the transmittance and the reflectance, respectively, of the case of the two-line system. Line 2301 indicating the transmittance shows that the high-efficiency range is substantially the same as the high-efficiency range indicated by line 1105 in FIG. 11, and that adjustment can be achieved with sufficient accuracy in the optimization program.

Line 2302 and line 2305 indicate the transmittance and the reflectance, respectively, of the case of three lines, whereas line 2303 and line 2306 indicate the transmittance and the reflectance, respectively, of the case of fourth lines, which show that the high-efficiency range increases as the number of lines increases. As the number of lines increases, the number of resonators increases and as a result the size of the apparatus increases, but it is understood that the benefits outweigh that.

Further, a case where an open-ring resonator and an LC resonator including a coil are used as the resonator of the resonance transfer apparatus has been described above, but the resonator is not limited to them. The present invention can be applied to resonators with which the coupling coefficient changes with no change in resonance frequency when the positional relationship between resonators changes and the reflection is zero when Equations (4) and (5) are satisfied with members other than coils and antennas as disclosed in NPL 5 that describes an example of coupling with electric field using an antenna instead of a coil.

While the present invention has been described in detail with reference to specific embodiments, these embodiments are presented by way of example and are not intended to limit the scope of the invention. The scope of the present disclosure is not limited to the specific embodiments described above and includes various modifications and variations thereof.

The alternating current signal transfer apparatus and the alternating current apparatus according to the present disclosure can perform highly efficient power transfer even when the positional relationship between resonators is changed.

The alternating current signal transfer apparatus of the present disclosure can suppress over a wide range the changes in transmission characteristics due to variations in the coupling coefficient, and thus can realize a stable non-contact power transfer apparatus with a simple and inexpensive configuration, while eliminating the need for a complicated adjustment circuit in non-contact power transfer. In addition, the present disclosure can contribute to the spread of electric vehicles that require frequent charging.
(1) An alternating current signal transfer apparatus of an embodiment of the present disclosure includes: a transmission line; a plurality of first phase shifters connected to the transmission line at a branching point; a plurality of resonator pairs each connected to each of the plurality of first phase shifters; and a plurality of second phase shifters each connected to each of the plurality of resonator pairs the plurality of second phase shifters are connected at a connecting point.
(2) In the alternating current signal transfer apparatus according to (1) of an embodiment of the present disclosure each of coupling coefficients of the plurality of resonator pairs is the same value even when a coupling state changes.
(3) In the alternating current signal transfer apparatus according to (1) of an embodiment of the present disclosure resonators of each of the plurality of resonator pairs include a coil and a capacitor.
(4) In the alternating current signal transfer apparatus according to (1) of an embodiment of the present disclosure resonators of each of the plurality of resonator pairs are open-ring resonators.
(5) In the alternating current signal transfer apparatus according to (1) of an embodiment of the present disclosure the transmission line is connected to a zero-ohm power source via a reactance element or an impedance line.
(6) In the alternating current signal transfer apparatus according to (2) of an embodiment of the present disclosure in the plurality of first phase shifters, phase shift angles are set such that matching is established at least at two of the coupling coefficients.
(7) An alternating current apparatus of an embodiment of the present disclosure includes: a transmission line; a plurality of phase shifters connected to the transmission line at a branching point; and a resonator connected to each of the plurality of phase shifters.
(8) In the alternating current apparatus according to (7) of an embodiment of the present disclosure the resonator includes a coil and a capacitor.
(9) In the alternating current apparatus according to (7) of an embodiment of the present disclosure the resonator is an open-ring resonator.
(10) In the alternating current apparatus according to (7) of an embodiment of the present disclosure a coupling coefficient of a resonator pair of the plurality of resonators is the same value even when a coupling state changes.
(11) In the alternating current apparatus according to (10) of an embodiment of the present disclosure in the plurality of phase shifters, phase shift angles are set such that matching is established at least at two of the coupling coefficients.

### INDUSTRIAL APPLICABILITY

The technology of the present disclosure can be utilized in an alternating current signal transfer apparatus and an alternating current apparatus.

### REFERENCE SIGNS LIST

110, 210 Load or power source
120, 220, 320, 350, 411, 422 Capacitor
130, 230 Coils
330, 413, 713, 733 Power transmitting coil
340, 423, 723, 743 Power receiving coil
310 Alternating current power source
360, 1320 Load
410, 420 Terminal
701 Input terminal
702, 752, 1916, 1926 Branching point
700 Resonance power transfer circuit
751 Output terminal
810, 820 Resonator coil substrate
830 Rotation axis of the resonator coil substrate
1310 Zero-ohm power source
1330 Resistor
1331 Capacitor
1332 Inductor
1333 Impedance line
1911, 1912, 1921, 1922 Open-ring resonator
1913 Input line
1914, 1915 Microstrip line serving as input-side phase shifter
1923 Output line
1924, 1925 Microstrip line serving as output-side phase shifter

1. An alternating current signal transfer apparatus comprising:
a transmission line;
a plurality of first phase shifters connected to the transmission line at a branching point;
a plurality of resonator pairs each connected to each of the plurality of first phase shifters; and
a plurality of second phase shifters each connected to each of the plurality of resonator pairs,
wherein the plurality of second phase shifters are connected at a connecting point.

2. The alternating current signal transfer apparatus according to claim 1,
wherein each of coupling coefficients of the plurality of resonator pairs is the same value even when a coupling state changes.

3. The alternating current signal transfer apparatus according to claim 1,
wherein resonators of each of the plurality of resonator pairs include a coil and a capacitor.

4. The alternating current signal transfer apparatus according to claim 1,
wherein resonators of each of the plurality of resonator pairs are open-ring resonators.

5. The alternating current signal transfer apparatus according to claim 1,
wherein the transmission line is connected to a zero-ohm power source via a reactance element or an impedance line.

6. The alternating current signal transfer apparatus according to claim 2,
wherein in the plurality of first phase shifters, phase shift angles are set such that matching is established at least at two of the coupling coefficients.

7. An alternating current apparatus comprising:
a transmission line;
a plurality of phase shifters connected to the transmission line at a branching point; and
a resonator connected to each of the plurality of phase shifters.

8. The alternating current apparatus according to claim 7,
wherein the resonator includes a coil and a capacitor.

9. The alternating current apparatus according to claim 7,
wherein the resonator is an open-ring resonator.

10. The alternating current apparatus according to claim 7,
wherein a coupling coefficient of a resonator pair of the plurality of resonators is the same value even when a coupling state changes.

11. The alternating current apparatus according to claim 10,
wherein in the plurality of phase shifters, phase shift angles are set such that matching is established at least at two of the coupling coefficients.
